(19) United States
(12) Patent Application Publication
(10) Pub. No.: US 2020/0302091 A1
(43) Pub. Date: Sep. 24, 2020

(54) INFORMATION PROCESSING APPARATUS, AND NON-TRANSITORY COMPUTER-READABLE STORAGE MEDIUM FOR STORING GEOMETRIC TOLERANCE AND DIMENSIONAL TOLERANCE CONVERSION PROGRAM

(71) Applicant: FUJITSU LIMITED, Kawasaki-shi (JP)

(72) Inventors: KAZUHIKO HAMAZOE, KAWASAKI (JP); Yoshikazu Ichikawa, Yokohama (JP); Tsukasa Tenma, Kawasaki (JP); Hirooki Hayashi, Kawasaki (JP); Ryusuke Akahoshi, Machida (JP); Mari Morimoto, Kawasaki (JP)

(73) Assignee: FUJITSU LIMITED, Kawasaki-shi (JP)

(21) Appl. No.: 16/784,307

(22) Filed: Feb. 7, 2020

(30) Foreign Application Priority Data
Mar. 18, 2019 (JP) 2019-049398

(51) Int. Cl. G06F 30/10

(52) U.S. Cl. CPC G06F 30/10

(57) ABSTRACT

An information processing apparatus includes: a memory configured to store correspondence information, the correspondence information including a word explaining each of a plurality of types of geometric tolerances using a dimensional tolerance method; and a processor coupled to the memory, the processor being configured to extract geometric tolerance information from drawing data in which the shape or structure of an article is defined by a geometric tolerance method, the geometric tolerance information including one or more of parameters thus set for the article, the one or more of parameters including at least any of a geometric tolerance type, a tolerance range, and a datum symbol, generate a word corresponding to the geometric tolerance information based on the correspondence information by referring to the memory, and output conversion result information including the generated word.

### CROSS-REFERENCE TO RELATED APPLICATION

This application is based upon and claims the benefit of priority of the prior Japanese Patent Application No. 2019-49398, filed on Mar. 18, 2019, the entire contents of which are incorporated herein by reference.

### FIELD

The embodiments discussed herein are related to an information processing apparatus, and a non-transitory computer-readable storage medium storing a geometric tolerance and dimensional tolerance conversion program.

### BACKGROUND

In the drawing creation process performed at the time of manufacturing various products, the drawing notation using a geometric tolerance method has recently attracted attention to reduce the ambiguity of interpretation in drawing notation using a dimensional tolerance method familiar in Japan, and to ensure the uniqueness of interpretation of design information. The drawing notation using the geometric tolerance method is more internationally common than the drawing notation using the dimensional tolerance method.

On the other hand, in 3D computer-aided design (CAD) technology, a 3D annotated model (3DA) is known, which is drawing data obtained by adding design information directly to a 3D model, In order to operate the 3DA efficiently, the drawing notation using the geometric tolerance method has been increasingly utilized, Along with this technical trend, the Japanese industrial standards (JIS) are being revised from the drawing notation using the dimensional tolerance method to the drawing notation using the geometric tolerance method.

Examples of the related art include Japanese Laid-open Patent Publication No. 2002-324094.

### SUMMARY

According to an aspect of the embodiments, an information processing apparatus includes: a memory configured to store correspondence information, the correspondence information including a word explaining each of a plurality of types of geometric tolerances using a dimensional tolerance method; and a processor coupled to the memory. The processor is configured to: extract geometric tolerance information from drawing data in which the shape or structure of an article is defined by a geometric tolerance method, the geometric tolerance information including one or more of parameters thus set for the article, the one or more of parameters including at least any of a geometric tolerance type, a tolerance range, and a datum symbol; generate a word corresponding to the geometric tolerance information based on the correspondence information by referring to the memory; and output conversion result information including the generated word.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of an information processing apparatus according to a first embodiment.

FIG. 2 is a block diagram illustrating a hardware example of the information processing apparatus.

FIG. 3 is a block diagram illustrating a functional example of the information processing apparatus.

FIG. 4 illustrates an example of a conversion table (Part 1).

FIG. 5 illustrates an example of a conversion table (Part 2).

FIG. 6 illustrates an example of a conversion table (Part 3).

FIG. 7 illustrates an example of an article whose shape or structure is defined by a geometric tolerance method.

FIG. 8 is a flowchart illustrating an exemplary flow of conversion into a word describing geometric tolerance information using a dimensional tolerance method.

FIG. 9 illustrates a storage example of a geometric tolerance DB.

FIG. 10 is a flowchart illustrating an exemplary flow of conversion processing when a geometric tolerance type is flatness.

FIG. 11 is a flowchart illustrating an exemplary lo of conversion processing when a geometric tolerance type is squareness.

FIG. 12 is a flowchart illustrating an exemplary flow of conversion processing when a geometric tolerance type is positional tolerance.

FIG. 13 illustrates a display example of conversion result information displayed on a display.

FIG. 14 is a diagram illustrating an example of displaying a group of selection buttons for selecting information to be displayed on the display.

FIG. 15 illustrates an example of displaying information on a measurement method together with the conversion result information.

FIG. 16 illustrates an example of simultaneously displaying some geometric tolerance information and the conversion result information on the display.

FIG. 17 illustrates an exemplary flow of processing for converting dimensional tolerance information into geometric tolerance information.

FIG. 18 illustrates an example in which a part of a certain article is defined by a dimensional tolerance method.

FIG. 19 illustrates a display example of candidates for a notation of a geometric tolerance method.

FIG. 20 is a diagram illustrating an example of a case where each candidate is applied.

### DESCRIPTION OF EMBODIMENT(S)

However, in actual sites (design sites, manufacturing sites, inspection sites, and the like), users of drawing data may be unfamiliar with the geometric tolerance method, and there are variations in interpretation of drawing data created using the geometric tolerance method, leading to a situation where the drawing data could not be used properly.

In one aspect, it is an object of the present disclosure to provide a geometric tolerance and dimensional tolerance conversion program and an information processing apparatus capable of suppressing variations in user interpretation of drawing data created using a geometric tolerance method.

In one aspect, the present disclosure enables suppression of variations in user interpretation of drawing data created using a geometric tolerance method.

Embodiments of the present disclosure will be described below with reference to the accompanying drawings.

### First Embodiment

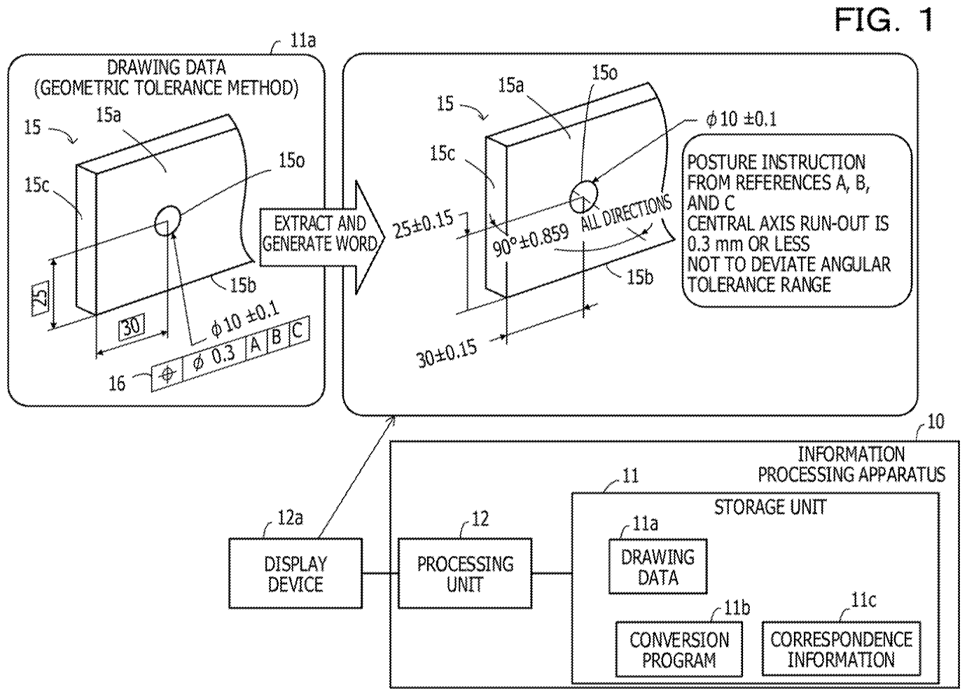

FIG. 1 illustrates an example of an information processing apparatus according to a first embodiment.

An information processing apparatus 10 includes a storage unit 11 and a processing unit 12.

The storage unit 11 includes drawing data 11a, a geometric tolerance and dimensional tolerance conversion program (hereinafter abbreviated as a conversion program) 11b, and correspondence information 11c, The storage unit 11 is a volatile storage device such as a random-access memory (RAM a non-volatile storage device such as a hard disk drive (HDD) or a flash memory, or a combination thereof.

The drawing data 11a includes, for example, data representing an article to be designed, manufactured, or inspected in 2D or 3D. In the drawing data 11a, the shape or structure of the article is defined by a geometric tolerance method. Information on the shape or structure of the article defined by the geometric tolerance method (hereinafter referred to as geometric tolerance information) is included in additional information created in association with the shape or structure of the article.

The drawing data 11a may be stored in another device (for example, an external storage device) coupled to the information processing apparatus 10.

The conversion program 11b is a program for converting (replacing) the geometric tolerance information into a word described using a dimensional tolerance method.

The correspondence information 11c includes a word describing each of a plurality of types of geometric tolerances using a dimensional tolerance method. Among the types of geometric tolerance methods, the types related to the shape include straightness, flatness, roundness, cylindricity, line contour, and circle contour, The types related to posture include parallelism, squareness, and inclination, the types related to position include positional tolerance, coaxiality, concentricity, and symmetry, and the types related to run-out include circumferential run-out and total run-out, The correspondence information 11c may include information indicating a calculation procedure (calculation method) for calculating a dimensional tolerance defined by the dimensional tolerance method using a tolerance range defined by the geometric tolerance method.

The drawing data 11a, the conversion program 11b, and the correspondence information 11c may be stored in different storage units.

The processing unit 12 may be a processor such as a central processing unit (CPU) or a digital signal processor (DSP). The processing unit 12 may include an application-specific electronic circuit such as an application-specific integrated circuit (ASIC) or a field-programmable gate array (FPGA). A set of the plurality of processors may be referred to as a “multiprocessor” or simply a “processor”.

The processing unit 12 performs the following processing by executing the conversion program lib stored in the storage unit 11. The processing unit 12 extracts geometric tolerance information including a geometric tolerance type, a tolerance range, and a datum symbol if any from the drawing data 11a, Then, the processing unit 12 generates a word corresponding to the extracted geometric tolerance information based on the correspondence information 11c by referring to the storage unit 11, and outputs conversion result information including the generated word. For example, the processing unit 12 outputs the conversion result information to a display device 12a coupled to the information processing apparatus 10, and displays the generated word on the display device 12a. The processing unit 12 may output the conversion result information to the storage unit 11 and store the conversion result information in the storage unit 11.

FIG. 1 illustrates an example of processing performed by the processing unit 12.

FIG. 1 illustrates an example of the drawing data 11a in which the position of a cylindrical opening 15o of an article 15 is defined using the positional tolerance of the geometric tolerance method.

A tolerance entry frame 16 indicates, from the left, a symbol indicating the positional tolerance, a tolerance range “φ0.3” indicating that a run-out tolerance from the central axis is 0.3 mm or less, and datum symbols “A”, “B”, and “C”. The datum symbols “A”, “B”, and “C” represent dimensional references (hereinafter simply referred to as references) when defining the posture of the shape. In FIG. 1, a triangular symbol representing a datum is omitted, but “A” is a datum symbol indicating a face 15a, “B” is a datum symbol indicating a face 15b, and “C” is a datum symbol indicating a face 15c. When the datum symbols are arranged in the order of “A”, “B”, and “C” in the tolerance entry frame 16, “A” has the highest priority and “C” has the lowest priority. The dimension (diameter) of the opening “φ10±0.1” is indicated as an additional symbol on the tolerance entry frame 16. Information as described above is extracted as geometric tolerance information.

The drawing data 11a further includes dimensional values “25” and “30” representing the distances from the faces 15b and 15c of the opening 15o as additional information.

The correspondence information 11c includes, for example, “posture instruction from the reference <Y> and a central axis run-out of <P1> mm or less not to deviate from an angular tolerance range” as an explanation of the positional tolerance related to the cylindrical opening 15o as described above. Based on the extracted geometric tolerance information, the processing unit 12 substitutes the datum symbols “A”, “B”, and “C” for <Y> in the above words, and substitutes “0.3” of the tolerance range “φ0.3” for <P1>. Thus, the words “posture instruction from references A, B, and C, and central axis run-out of 0.3 mm or less not to deviate from angular tolerance range” are generated as illustrated in FIG. 1.

The processing unit 12 calculates dimensional tolerances sing the information indicating the calculation procedure for calculating the dimensional tolerance defined by the dimensional tolerance method using the tolerance range defined by the geometric tolerance method, which is included in the correspondence information 11c. FIG. 1 illustrates an example where the dimensional tolerance “±0.15” from the faces 15b and 15c to the central axis of the opening 15o is calculated based on the tolerance range “φ0.3”. The processing unit 12 acquires the maximum length (here, 10 mm) in the direction perpendicular to the face 15a in the opening 15o from additional information, for example, and calculates±(tan⁻¹ (0.3/10)/2))=±0.859 as an angular tolerance range that is a dimensional tolerance. The processing unit 12 outputs conversion result information including dimensional information with the calculated dimensional tolerance added to the dimensional value.

As described above, the information processing apparatus 10 according to the first embodiment extracts geometric tolerance information from the drawing data 11a, and generates words describing the geometric tolerance information using the dimensional tolerance method based on the correspondence information 11c. Thus, even a user who is unfamiliar with the geometric tolerance method may easily understand the drawing data 11a created by using the geometric tolerance method, thus enabling suppression of variations in user interpretation.

For example, since variations in user interpretation of the drawing data 11a may be suppressed at the manufacturing site, interpretation errors of important items such as how much accuracy to be secured may be reduced, and manufacturing defects and yield deterioration may be suppressed. Since variations in user interpretation of the drawing data 11a may also be suppressed at the inspection site, the possibility of adopting an erroneous inspection method may be reduced, and an increase in inspection man hours due to unknown inspection method may be suppressed. It becomes easier at the design site to check if the intended design information is included when a designer uses the geometric tolerance method to create the drawing data 11a, and thus the quality of the drawing data 11a may be improved.

### Second Embodiment

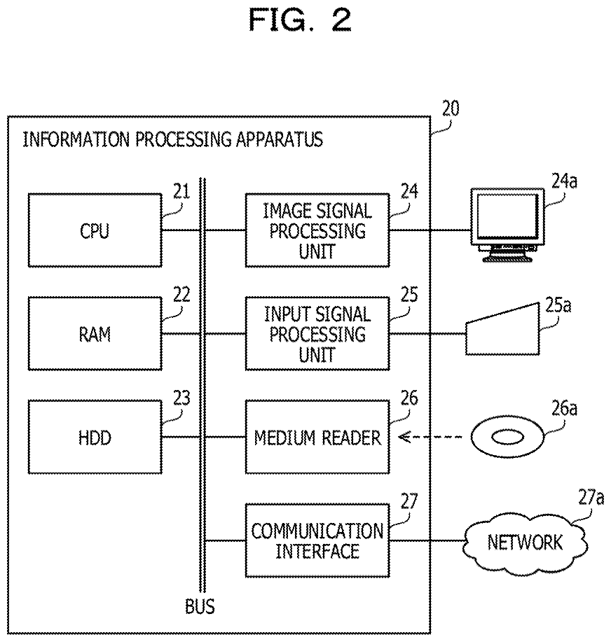

FIG. 2 is a block diagram illustrating a hardware example of the information processing apparatus.

The information processing apparatus 20 includes a CPU 21, a RAM 22, an HDD 23, an image signal processing unit 24, an input signal processing unit 25, a medium reader 26, and a communication interface 27. The above units are coupled to a bus.

The CPU 21 is a processor including an arithmetic circuit that executes program instructions. The CPU 21 loads at least a part of a program and data stored in the HDD 23 into the RAM 22 and executes the program. The CPU 21 may include a plurality of processor cores, the information processing apparatus 20 may include a plurality of processors, and the processes described below may be executed in parallel using a plurality of processors or processor cores, A set of the plurality of processors may be referred to as a “multiprocessor” or simply a “processor”.

The RAM 22 is a volatile semiconductor memory that temporarily stores a program executed by the CPU 21 and data used for computation by the CPU 21. The information processing apparatus 20 may include a type of memory other than the RAM, and may include a plurality of memories.

The HDD 23 is a non-volatile storage device that stores software programs such as an operating system (OS), middleware, and application software, and data. The program includes, for example, a conversion program that causes the information processing apparatus 20 to execute processing for converting (replacing) geometric tolerance information included in the drawing data into the words described using the dimensional tolerance method. The information processing apparatus 20 may include other types of storage devices such as a flash memory and a solid state drive (SSD), and may include a plurality of non-volatile storage devices.

The image signal processing unit 24 outputs an image to a display 24a coupled to the information processing apparatus 20 in accordance with a command from the CPU 21. As the display 24a, a cathode ray tube (CRT) display, a liquid crystal display (LCD), a plasma display panel (PDP), an organic EL (organic electro-luminescence: OEL) display, or the like may be used.

The input signal processing unit 25 acquires an input signal from an input device 25a coupled to the information processing apparatus 20 and outputs the input signal to the CPU 21. As the input device 25a, a pointing device such as a mouse, a touch panel, or a trackball, a keyboard, a remote controller, a button switch, and the like may be used, A plurality of types of input devices may be coupled to the information processing apparatus 20.

The medium reader 26 is a reading device that reads a program or data recorded on a recording medium 26a. As the recording medium 26a, for example, a magnetic disk, an optical disk, a magneto-optical disk (MO), a semiconductor memory, and the like may be used. The magnetic disk includes a flexible disk (FD) and an HDD. The optical disk includes a compact disc (CD) and a digital versatile disc (DVD).

The medium reader 26 copies a program or data read from the recording medium 26a to another recording medium such as the RAM 22 or the HDD 23, for example. The read program is executed by the CPU 21, for example. The recording medium 26a may be a portable recording medium or may be used to distribute the program or data. The recording medium 26a and the HOD 23 may be referred to as computer-readable recording media.

The communication interface 27 is coupled to a network 27a and communicates with another information processing apparatus via the network 27a. The communication interface 27 may be a wired communication interface coupled to a communication device such as a switch via a cable, or may be a wireless communication interface coupled to a base station via a wireless link.

Next, functions and processing procedures of the information processing apparatus 20 will be described.

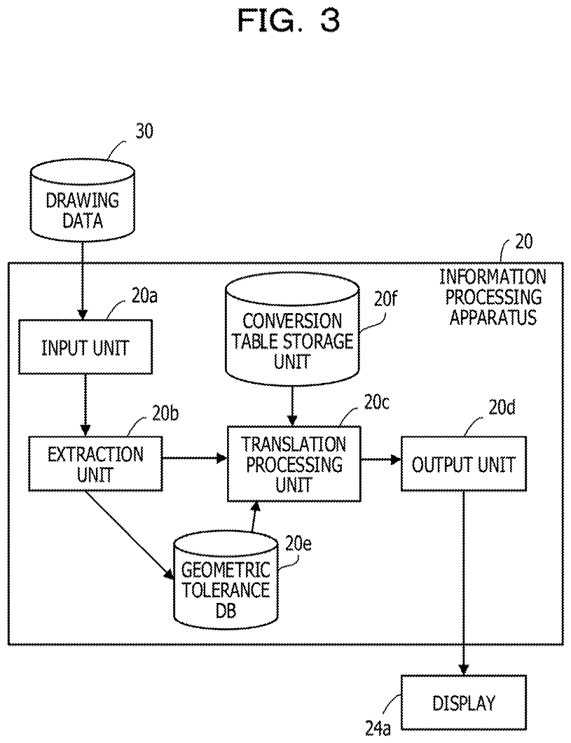

FIG. 3 is a block diagram illustrating a functional example of the information processing apparatus.

The information processing apparatus 20 includes an input unit 20a, an extraction unit 20b, a translation processing unit 20c, an output unit 20d, a geometric tolerance database (DB) 20e, and a conversion table storage unit 20f. The input unit 20a, the extraction unit 20b, the translation processing unit 20c, and the output unit 20d may be mounted using, for example, a program module executed by the CPU 21. The geometric tolerance DB 20e and the conversion table storage unit 20f may be mounted using a storage area secured in the RAM 22 or the HDD 23, for examples.

For example, the input unit 20a reads drawing data 30 from the outside of the information processing apparatus 20 (for example, a device coupled to the recording medium 26a or the network 27a) and stores the drawing data 30 in the RAM 22 or the HDD 23. The drawing data 30 may be stored in the HDD 23 in advance. The input unit 20a may acquire an input signal generated by the user operating the input device 25a.

The extraction unit 20b extracts information including the lead lines (additional information) from the drawing data 30, and extracts geometric tolerance information from the additional information. The extraction unit 20b stores the extracted geometric tolerance information in the geometric tolerance DB 20e.

The translation processing unit 20c refers to the conversion table storage unit 20f and generates words corresponding to the geometric tolerance information stored in the geometric tolerance DB 20e based on the conversion table.

The output unit 20d outputs the conversion result information including the words generated by the translation processing unit 20c to the display 24a, for example, to display the conversion result information.

The geometric tolerance DB 20e stores the geometric tolerance information extracted by the extraction unit 20b. A storage example of the geometric tolerance information will be described later.

The conversion table is stored in advance in the conversion table storage unit 20f. The conversion table is an example of the correspondence information described above, and includes words describing each of a plurality of types of geometric tolerances using a dimensional tolerance method. The conversion table also includes information indicating a calculation procedure for calculating a dimensional tolerance defined by the dimensional tolerance method using a tolerance range defined by the geometric tolerance method.

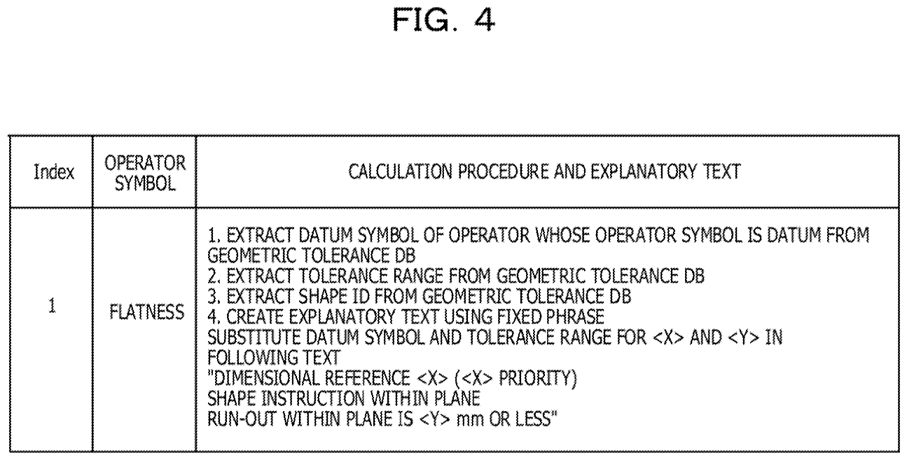

FIGS. 4 to 6 illustrate an exemplary conversion table.

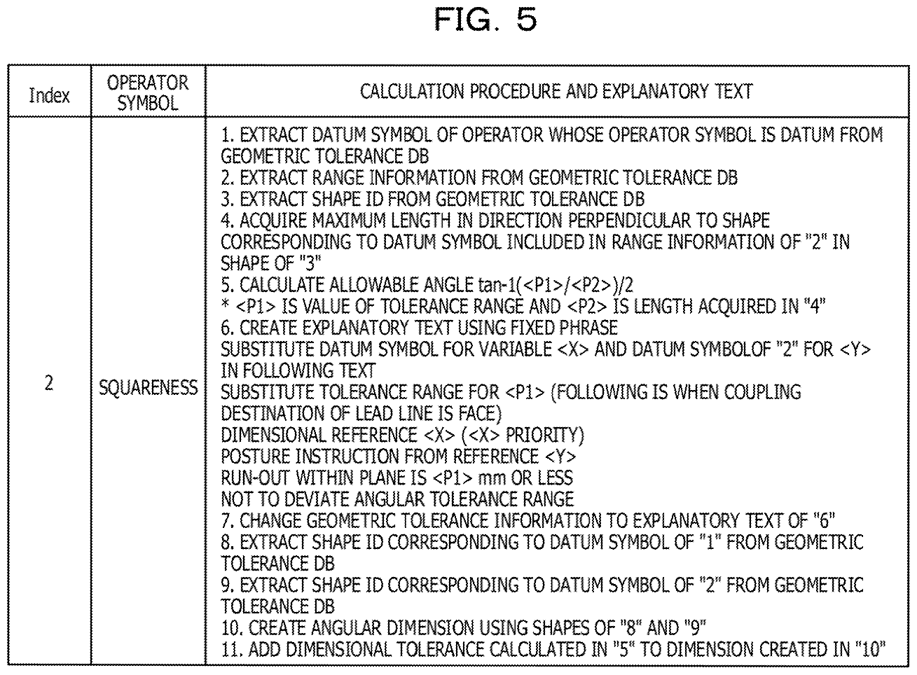

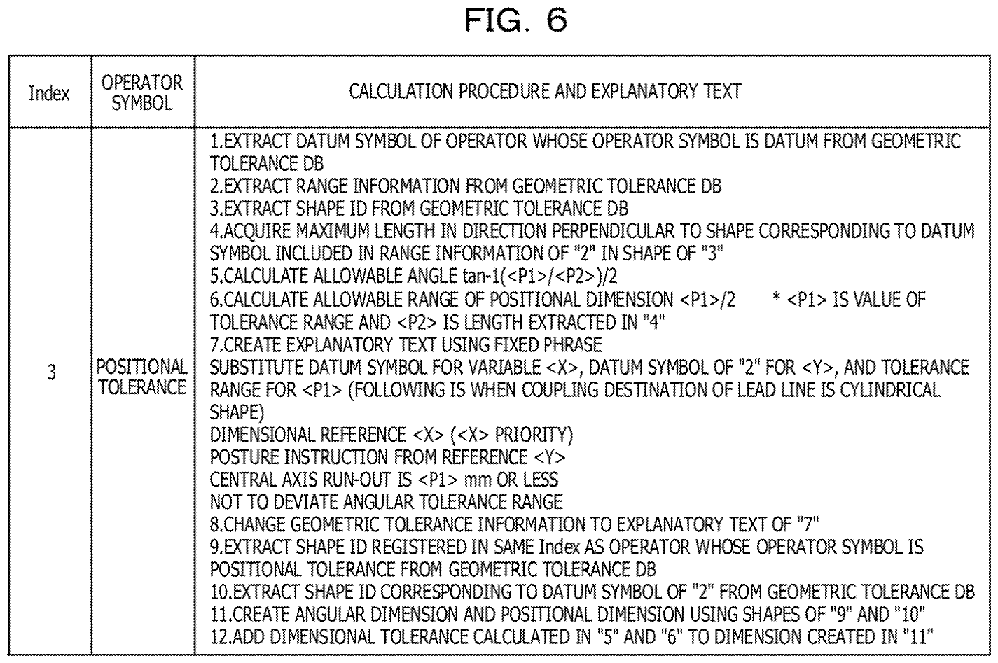

Index=1 (FIG. 4) in the conversion table represents a calculation procedure and explanatory text for flatness, and Index=2 (FIG. 5) represents a calculation procedure and explanatory text for squareness. Index=3 (FIG. 6) represents a calculation procedure and explanatory text for positional tolerance, The calculation procedure and explanatory text in each Index will be described later.

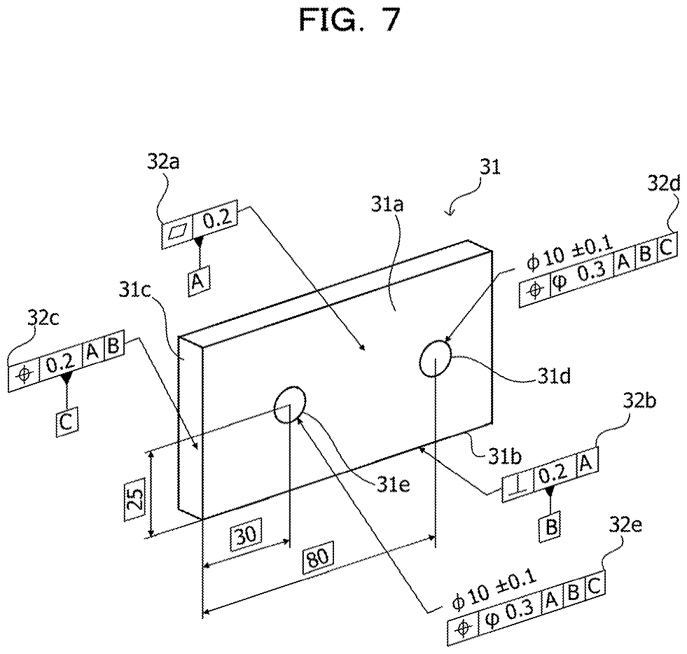

FIG. 7 illustrates an example of an article whose shape or structure is defined by the geometric tolerance method.

In FIG. 7, the shape or structure of an article 31 is defined by the geometric tolerance method.

A tolerance entry frame 32a represents, from the left, a symbol representing flatness and a tolerance range “0.2” indicating that a run-out tolerance within the plane is 0.2 mm or less. In the tolerance entry frame 32a, a datum symbol “A” indicating a face 31a serving as a dimensional reference is added to the triangular symbol representing the datum.

A tolerance entry frame 32b represents, from the left, a symbol representing a squareness, a tolerance range “0.2” indicating that the run-out tolerance within the plane is 0.2 mm or less, and a datum symbol “A” representing the shape posture reference. A datum symbol “B” indicating a face 31b (lower surface of the article 31 in FIG. 7) serving as a dimensional reference is added to the triangular symbol representing the datum.

A tolerance entry frame 32c represents, from the left, a symbol indicating the positional tolerance, a tolerance range “0.2” indicating that the run-out tolerance within the plane is 0.2 mm or less, and the datum symbols “A” and “B” indicating the shape posture references. A datum symbol “C” indicating a face 31c serving as a dimensional reference is added to the triangular symbol representing the datum.

Each of tolerance entry frames 32d and 32e represents, from the left, a symbol indicating the positional tolerance, a tolerance range “φ0.3” indicating that a run-out tolerance from the central axis of the cylindrical openings 31d and 31e is 0.3 mm or less”, and the datum symbols “A”, “B”, and “C” representing the shape posture references. The dimension (diameter) “φ10±0.1” of the opening is indicated as an additional symbol on the tolerance entry frames 32d and 32e.

Besides the above, in FIG. 7, dimensional values “25”, “30”, and “80” representing the positions of the openings 31d and 31e are defined.

The drawing data 30 includes, for example, information defining the shape or structure of the article 31 as additional information in addition to the 3D data of the article 31 as described above.

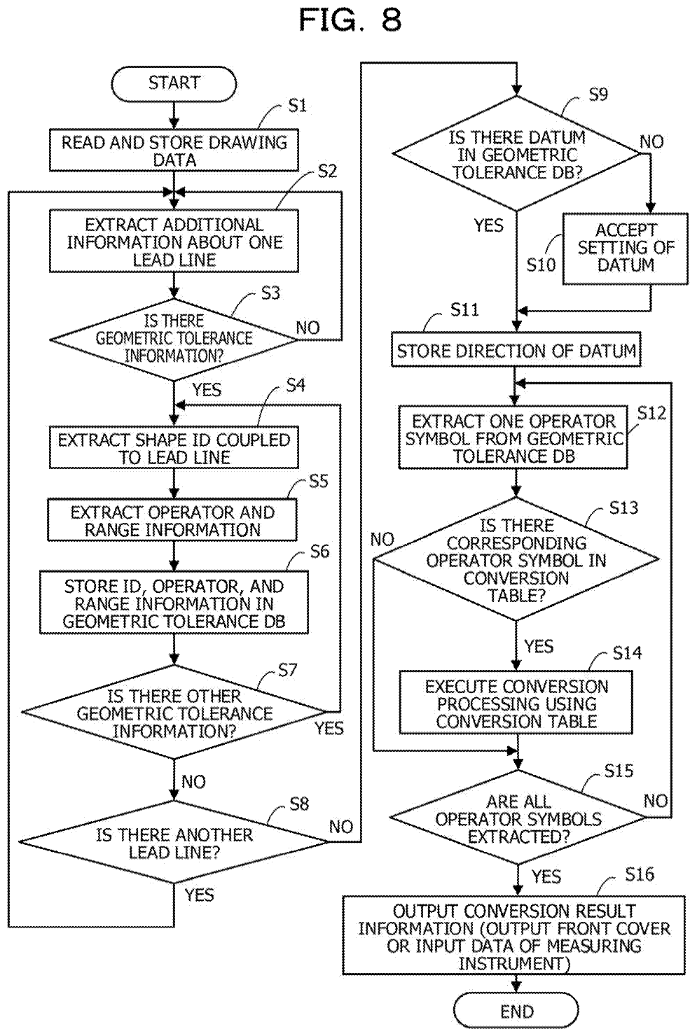

FIG. 8 is a flowchart illustrating an exemplary processing flow of conversion into a word describing geometric tolerance information using a dimensional tolerance method.

(S1) The input unit 20a reads the drawing data 30 from the outside of the information processing apparatus 20, for example. The extraction unit 20b stores the read drawing data 30 in the RAM 22 or the HDD 23, for example.

(S2) The extraction unit 20b extracts additional information for one lead line from the drawing data 30. As illustrated in FIG. 7, additional information about the lead line coupled to the face 31a is first extracted, for example, from the drawing data 30 including the additional information defining the article 31.

(S3) The extraction unit 20b determines whether or not the extracted additional information includes geometric tolerance information. When the extracted additional information includes no geometric tolerance information, the processing of Step S2 is repeated for another lead line. When the extracted additional information includes geometric tolerance information, the processing of Step S4 is performed. In the above example, since the additional information includes geometric tolerance information including an operator representing flatness, which is a type of geometric tolerance, a tolerance range, and a datum symbol, the processing of Step S4 is performed.

(S4) The extraction unit 20b extracts the ID of the shape coupled to the lead line from the drawing data 30. In the above example, the ID of the face 31a is extracted.

(S5) The extraction unit 20b extracts the operator and range information as geometric tolerance information from the additional information. The operator indicates the type of geometric tolerance or datum. In the following, operator symbols representing operators include datum and each type of geometric tolerance, and these are separate geometric tolerance information. When the operator symbol is a datum, the range information is a datum symbol of the datum. When the operator symbol is a geometric tolerance type, the range information includes information other than the symbol indicating the geometric tolerance type (tolerance range and datum symbol) among the information indicated in the tolerance entry frame as illustrated in FIG. 7. In the following description, an additional symbol (for example, “φ10±0.1” in FIG. 7) is also one of operators different from each type of datum and geometric tolerance, but is extracted as range information without any operator symbol.

(S6) The extraction unit 20b stores the shape ID, operator, and range information extracted in the processing of Steps S4 and S5 in the geometric tolerance DB 20e. For example, the ID of the face 31a of the article 31 illustrated in FIG. 7, the datum as the operator symbol, and the datum symbol “A” as the range information are first stored in the geometric tolerance DB 20e.

(S7) The extraction unit 20b determines whether or not the additional information about one lead line includes other geometric tolerance information. When there is other geometric tolerance information, the processing from Step S4 is repeated, and when there is no other geometric tolerance information, the processing of Step S8 is performed.

(S8) The extraction unit 20b determines whether or not there is another lead line (for which no additional information is extracted). When there is another lead line, the processing from Step S2 is repeated, and when there is no other lead line, the processing of Step S9 is performed.

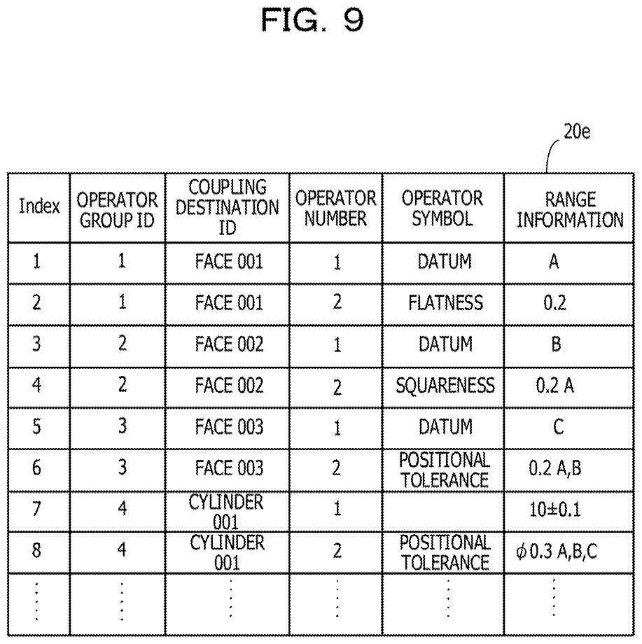

FIG. 9 illustrates a storage example of a geometric tolerance D.

For Index=1 in the geometric tolerance DB 20e, “face 001” as the ID (written as coupling destination ID) of the face 31a of the article 31 illustrated in FIG. 7, a datum as an operator symbol, the datum symbol “A” as range information are registered as geometric tolerance information. For Index=2, “face 001”, flatness as an operator symbol, and a tolerance range “0.2” as range information are registered as other geometric tolerance information about the lead line coupled to the face 31a.

The same operator group ID is assigned to the geometric tolerance information for the same lead line, and different operator numbers are assigned to different geometric tolerance information for the same lead line.

For Index=3 in the geometric tolerance DB 20e, “face 002” as the ID of the face 31b of the article 31 illustrated in FIG. 7, the datum as the operator symbol, and the datum symbol “B” as the range information” are registered as the geometric tolerance information, For Index=4, “face 002”, squareness as an operator symbol, a tolerance range “0.2” as range information, and the datum symbol “A” are registered as other geometric tolerance information about the lead line coupled to the face 31b.

For Index=5 in the geometric tolerance DB 20e, “face 003” as the ID of the face 31c of the article 31 illustrated in FIG. 7, the datum that is the operator symbol, and the datum symbol “C” as the range information” are registered as the geometric tolerance information, For Index=6, “face 003”, the positional tolerance as an operator symbol, a tolerance range “0.2” as range information, and the datum symbols “A” and “B” are registered as other geometric tolerance information about the lead line coupled to the face 31c.

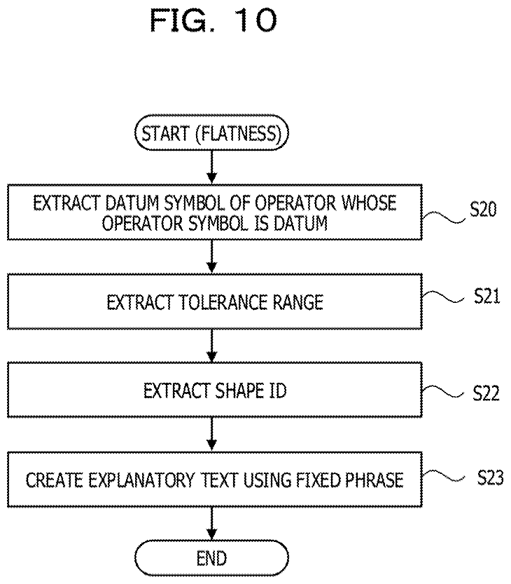

For Index=7 in the geometric tolerance DB 20e, “cylinder 001” as the ID of the cylindrical opening 31d of the article 31 illustrated in FIGS. 7 and 10 ±0.1 as the range information are registered as geometric tolerance information (no operator symbol). For Index=8, “cylinder 001”, positional tolerance as an operator symbol, a tolerance range “φ0.3” as range information, and the datum symbols “A”, “B”, and “C” are registered as other geometric tolerance information about the lead line coupled to the opening 31d.

(S9) The translation processing unit 20c determines whether or not a datum is included (registered) as an operator symbol in the geometric tolerance DB 20e, When there is no datum, the processing of Step S10 is performed, and when there is a datum, the processing of Step S11 is performed.

(S10) When there is no datum, there is a possibility of mistake made by the designer in creating the drawing data 30, and therefore, the input unit 20a accepts the setting of the datum by the user. In this event, for example, the translation processing unit 20c generates a message indicating that the drawing data 30 includes no datum, and causes the output unit 20d to output the message to the display 24a together with the 3D image of the article 31. For example, the user refers to the 3D image of the article 31 displayed on the display 24a to select a shape to be set as a datum using the input device 25a. The set datum Information (datum symbol and shape ID set as the datum) is inputted to the input unit 20a and registered in the geometric tolerance DB 20e. The inputted datum information may be registered to the geometric tolerance information of the drawing data 30 stored in the RAM 22 or the HDD 23.

(S11) When it is determined in Step S9 that there is a datum, or after the processing of Step S10, the translation processing unit 20c uses the ID of the shape set as the datum, refers to the drawing data 30 to detect the direction of the datum, and stores the direction in the RAM 22, for example. When the datum is a face, the direction is the normal direction of the face defined in the drawing data 30.

(S12) Next, the translation processing unit 20c extracts one operator symbol from the geometric tolerance DB 20e. The operator symbols are extracted in the order of Index in the geometric tolerance DB 20e, for example.

(S13) The translation processing unit 20c refers to the conversion table storage unit 20f to determine whether or not an operator symbol corresponding to the extracted operator symbol is included in the conversion table. When the corresponding operator symbol is included in the conversion table, the processing of Step S14 is performed, and when the corresponding operator symbol is not included in the conversion table, the processing of Step S15 is performed.

(S14) When the corresponding operator symbol is included in the conversion table, the translation processing unit 20c uses the conversion table to perform conversion processing corresponding to the type of geometric tolerance indicated by the operator symbol. An example of the processing in Step S14 will be described later.

(S15) The translation processing unit 20c determines whether or not all operator symbols have been extracted from the geometric tolerance DB 20e. When all the operator symbols have not been extracted, the processing from Step S12 is repeated, and when all the operator symbols have been extracted, the processing of Step S16 is performed.

(S16) The output unit 20d outputs the conversion result information including the words generated by the translation processing unit 20c to the display 24a, for example, to display the conversion result information. The output unit 20d may output the conversion result information as input data of a measuring instrument used during inspection process, for example.

A processing example of Step S14 will be described below.

FIG. 10 is a flowchart illustrating an exemplary flow of conversion processing when a geometric tolerance type is flatness.

When the operator symbol extracted from the geometric tolerance DB 20e in Step S12 represents flatness, the translation processing unit 20c performs the following processing based on the conversion table illustrated in FIG. 4.

(S20) The translation processing unit 20c extracts, from the geometric tolerance DB 20e, the datum symbol of the operator whose operator symbol is a datum in the same operator group (having the same operator group ID) as the operator symbol extracted in Step S12. For example, when the operator symbol of Index=2 is extracted from the geometric tolerance DB 20e illustrated in FIG. 9 in the processing of Step S12, the operator symbol of the operator of Index=1 with the same operator group ID=1 is the datum. Therefore, the datum symbol “A” registered as the range information about the operator is extracted.

(S21) The translation processing unit 20c extracts, from the geometric tolerance DB 20e, a tolerance range registered as range information in the same Index as the operator symbol extracted in Step S12. For example, when the operator symbol of Index=2 is extracted from the geometric tolerance DB 20e illustrated in FIG. 9 in the processing of Step S12, the tolerance range “0.2” registered as the range information is extracted.

(S22) The translation processing unit 20c extracts, from the geometric tolerance DB 20e, the ID (coupling destination ID) of the shape registered in the same Index as the operator symbol extracted in Step S12. For example, when the operator symbol of Index=2 is extracted from the geometric tolerance DB 20e illustrated in FIG. 9 in the processing of Step S12, the coupling destination ID “face 001” is extracted.

(S23) The translation processing unit 20c creates an explanatory text using a fixed phrase indicated in the conversion table illustrated in FIG. 4, and terminates the conversion processing for flatness.

As illustrated in FIG. 4, the fixed phrase for flatness is “dimensional reference <X> (<X> priority), with shape instruction within plane, run-out within plane is <Y> mm or less”, The translation processing unit 20c substitutes the datum symbol extracted in Step S20 for <X>, and substitutes the tolerance range extracted in Step S21 for <Y>.

As described above, the conversion table includes a word indicating that the shape corresponding to the datum symbol is set as a reference (dimensional reference) in the dimensional tolerance method, and a word indicating the priority order of the references, The translation processing unit 20c creates an explanatory text using the above words, so that the user may easily understand the meaning of the datum symbol, A tolerance range that is not expressed by the dimensional tolerance method, such as a run-out tolerance within a plane, may be expressed by the words (note information) as described above.

The shape ID extracted in Step S22 is associated with the explanatory text created in Step S23, and is held in the RAM 22, for example. Then, in the processing of Step S16 described above, the explanatory text is displayed in association with the face indicated by the ID.

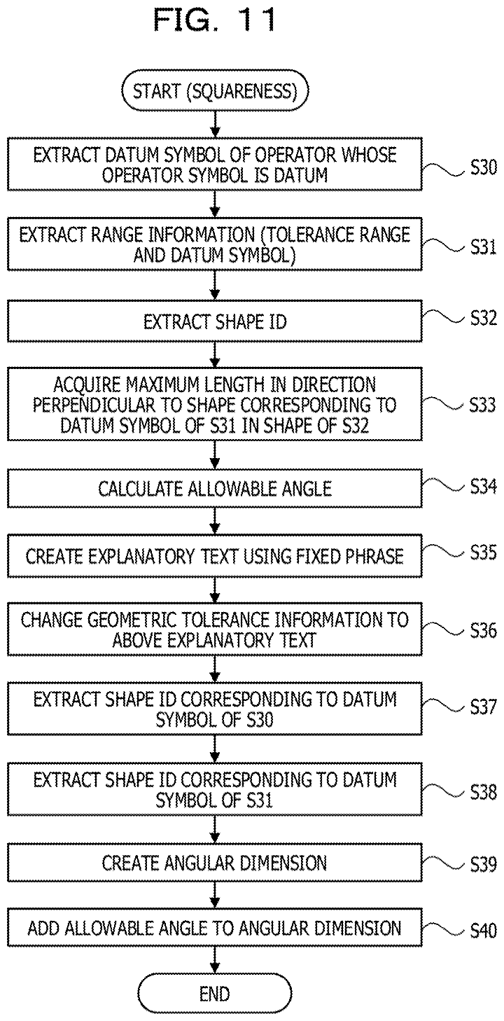

FIG. 11 is a flowchart illustrating an exemplary flow of conversion processing when a geometric tolerance type is squareness.

When the operator symbol extracted from the geometric tolerance DB 20e in Step S12 represents squareness, the translation processing unit 20c performs the following processing based on the conversion table illustrated in FIG. 5.

(S30) The translation processing unit 20c extracts, from the geometric tolerance DB 20e, a datum symbol of an operator whose operator symbol is a datum in the same operator group as the operator symbol extracted in Step S12. For example, when the operator symbol of Index=4 is extracted from the geometric tolerance DB 20e illustrated in FIG. 9 in the processing of Step S12, the operator symbol of Index=3 having the same operator group ID=2 is a datum, and thus the datum symbol “B” registered as the range information is extracted.

(S31) The translation processing unit 20c extracts range information (tolerance range and datum symbol) registered in the same Index as the operator symbol extracted in Step S12 from the geometric tolerance DB 20e. For example, when the operator symbol of Index=4 is extracted from the geometric tolerance DB 20e illustrated in FIG. 9 in the processing of Step S12, the tolerance range “0.2” and the datum symbol “A” registered as range information are Extracted.

(S32) The translation processing unit 20c extracts, from the geometric tolerance DB 20e, the ID (coupling destination ID) of the shape registered in the same Index as the operator symbol extracted in Step S12. For example, when the operator symbol of Index=4 is extracted from the geometric tolerance DB 20e illustrated in FIG. 9 in the processing of Step S12, the coupling destination ID “face 002” is extracted.

(S33) The translation processing unit 20c acquires the maximum length in the direction perpendicular to the shape corresponding to the datum symbol extracted in Step S31 in the shape indicated by the ID extracted in Step S32. For example, as described above, it is assumed that the datum symbol “A” is extracted in Step S31, and the coupling destination ID “face 002” is extracted in Step S32. In that case, the translation processing unit 20c acquires, from the additional information, the maximum length in the direction perpendicular to the face 31a on the face 31b (lower face of the article 31) illustrated in FIG. 7.

(S34) The translation processing unit 20c calculates the allowable angle based on the calculation procedure indicated in the conversion table illustrated in FIG. 5. The allowable angle may be calculated by calculating tan⁻¹(<P1>/<P2>)/2. The translation processing unit 20c calculates the allowable angle by substituting the numerical value of the tolerance range extracted in Step S31 for <P1> and substituting the length acquired in Step S33 for <P2>. For example, when the tolerance range is “0.2” and the length is 10 mm, the allowable angle is tan⁻¹(0.2/10)/2=0.573° with respect to both the positive and negative directions. In other words, in the case of adopting the center distribution, which is a method of expressing the dimensional tolerance of the dimensional tolerance method, the allowable angle is “±0.573°”.

(S35) The translation processing unit 20c creates an explanatory text using the fixed phrase indicated in the conversion table illustrated in FIG. 5.

As illustrated in FIG. 5, the fixed phrase for squareness is “dimensional reference <X> (<X> priority)”, posture instruction from reference <Y>, run-out within plane is <P1> mm or less not to deviate from the angle tolerance range when coupling destination of lead line is face. The translation processing unit 20c substitutes the datum symbol extracted in Step S30 for <X>, substitutes the datum symbol extracted in Step S31 for <Y>, and substitutes the tolerance range extracted in Step S31 for <P1>.

(S36) The translation processing unit 20c changes the geometric tolerance information for the same operator group as the operator symbol extracted in Step S12 to the explanatory text created in Step S35 (the original geometric tolerance information may be left separately).

(S37) The translation processing unit 20c extracts the shape ID corresponding to the datum symbol extracted in Step S30 from the geometric tolerance DB 20e.

(S38) The translation processing unit 20c extracts the shape ID corresponding to the datum symbol extracted in Step S31 from the geometric tolerance DB 20e.

(S39) The translation processing unit 20c creates an angular dimension between the two shapes from the shape IDs extracted in Steps S37 and S38. For example, it is assumed that the shape ID extracted in Step S37 is “face 002” and the shape ID extracted in. Step S38 is “face 001”. In that case, the translation processing unit 20c creates an angular dimension that represents an angle between the normal direction of the face 31a and the normal direction of the face 31b, using the direction of the datum stored in advance. The translation processing unit 20c may perform processing of moving the starting point of the dimension line of the angular dimension to the ends of the faces 31a and 31b.

(S40) The translation processing unit 20c generates dimensional information in which the allowable angle (dimensional tolerance) calculated in S34 is added to the angular dimension created in Step S39, and terminates the conversion processing for squareness.

The shape ID extracted in Step S32 is held in the RAM 22, for example, in association with the explanatory text created in Step S33 and the dimensional information obtained in Step S40. Then, in the processing of Step S16 described above, the explanatory text and dimensional information are displayed in association with the shape indicated by the ID.

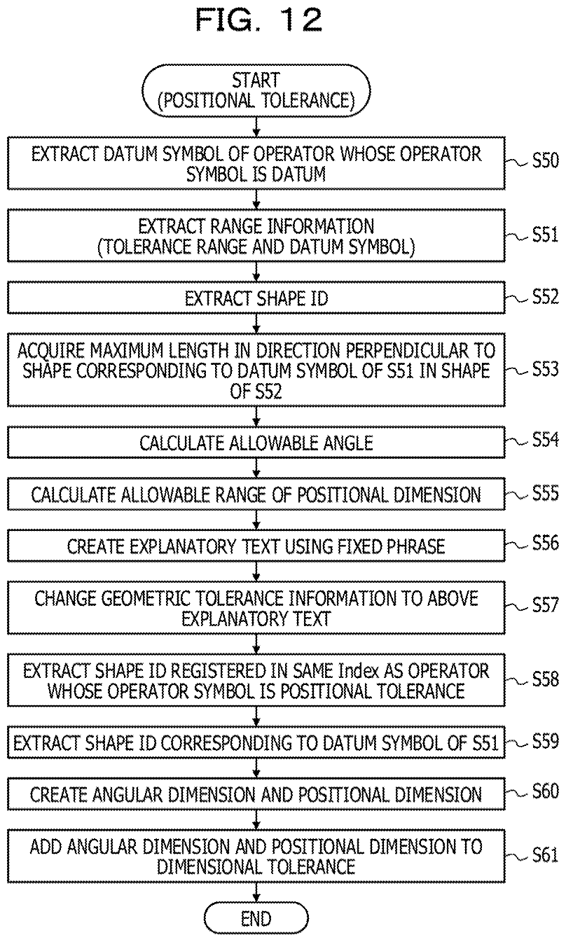

FIG. 12 is a flowchart illustrating an exemplary flow of conversion processing when a geometric tolerance type is positional tolerance.

When the operator symbol extracted from the geometric tolerance DB 20e in Step S12 represents the positional tolerance, the translation processing unit 20c performs the following processing based on the conversion table illustrated in FIG. 6.

(S50) The translation processing unit 20c extracts, from the geometric tolerance DB 20e, a datum symbol of an operator whose operator symbol is a datum in the same operator group as the operator symbol extracted in Step S12. For example, when the operator symbol of Index=6 is extracted from the geometric tolerance DB 20e illustrated in FIG. 9 in the processing of Step S12, the operator symbol of Index=5 having the same operator group ID=3 is a datum, and thus the datum symbol “C” registered as the range information is extracted. On the other hand, when an operator symbol of Index=8 is extracted from the geometric tolerance DB 20e illustrated in FIG. 9, no datum symbol is extracted because there is no operator whose operator symbol is a datum with the same operator group ID=4.

(S51) The translation processing unit 20c extracts range information (tolerance range and datum symbol) registered in the same Index as the operator symbol extracted in Step S12 from the geometric tolerance DB 20e. For example, when the operator symbol of Index=6 is extracted from the geometric tolerance DB 20e illustrated in FIG. 9 in the processing of Step S12, the tolerance range “0.2” and the datum symbols “A”, “B” registered as the range information are extracted. When the operator symbol of Index=8 is extracted from the geometric tolerance DB 20e illustrated in FIG. 9, the tolerance range “φ0.3” and the datum symbols “A”, “B”, “C” registered as the range information are extracted.

(S52) The translation processing unit 20c extracts the ID (coupling destination ID) of the shape registered in the same Index as the operator symbol extracted in the processing of Step S12 from the geometric tolerance DB 20e. For example, when the operator symbol of Index=6 is extracted from the geometric tolerance DB 20e illustrated in FIG. 9 in the processing of Step S12, the coupling destination ID “face 003” is extracted. When the operator symbol of Index=8 is extracted from the geometric tolerance DB 20e illustrated in FIG. 9, the coupling destination ID “cylinder 001” is extracted.

(S53) The translation processing unit 20c acquires the maximum length in the direction perpendicular to the shape corresponding to the datum symbol (highest priority datum symbol) extracted in Step S51 in the shape indicated by the ID extracted in Step S52. For example, as described above, it is assumed that the datum symbols “A” and “B” are extracted in Step S51 and the coupling destination ID “face 003” is extracted in Step S52. In that case, the translation processing unit 20c acquires, from the additional information, the maximum length in the direction perpendicular to the face 31a corresponding to the highest priority datum symbol “A” on the face 31c illustrated in FIG. 7. On the other hand, it is assumed that the datum symbols “A”, “B”, and “C” are extracted in Step S51 and the coupling destination ID “cylinder 001” is extracted in Step S52. In that case, the translation processing unit 20c acquires, from the additional information, the maximum length in the direction perpendicular to the face 31a corresponding to the highest priority datum symbol “A” in the opening 31d illustrated in FIG. 7.

(S54) The translation processing unit 20c calculates an allowable angle based on the calculation procedure depicted in the conversion table illustrated in FIG. 6. The allowable angle may be calculated by calculating tan⁻¹(<P1>/<P2>)/2. The translation processing unit 20c calculates the allowable angle by substituting the numerical value of the tolerance range extracted in Step S51 for <P1> and substitutes the length acquired in Step S53 for <P2>. For example, when the tolerance range is “φ0.3” and the length is 10 mm, the allowable angle is tan⁻¹(0.3/16)/2=0.859° with respect to both positive and negative directions. In other words, in the case of adopting the center distribution, which is a method of expressing the dimensional tolerance of the dimensional tolerance method, the allowable angle is “±0.859°”.

(S55) The translation processing unit 20c calculates the allowable range of the positional dimension based on the calculation procedure indicated in the conversion table illustrated in FIG. 6. The allowable range of the positional dimension may be calculated by calculating <P1>/2. The translation processing unit 20c calculates the allowable range of the positional dimension by substituting the numerical value of the tolerance range extracted in Step S51 for <P1>. For example, when the tolerance range is “φ0.3”, the allowable range of the positional dimension is 0.3/2=0.15 in both the positive and negative directions. That is, in the case of adopting the center distribution, which is a method of expressing the dimensional tolerance of the dimensional tolerance method, the positional dimension is “±0.15”.

(S56) The translation processing unit 20c creates an explanatory text by using the fixed phrase indicated in the conversion table illustrated in FIG. 6.

As illustrated in FIG. 6, when the coupling destination of the lead line is a cylindrical shape (including the cylindrical openings 31d and 31e as illustrated in FIG. 7), the fixed phrase for the positional tolerance is as follows, “Dimensional reference <X> (<X> priority), posture instruction from reference <Y>, central axis run-out is <P1> mm or less not to deviate from angular tolerance range”. The translation processing unit 20c substitutes the datum symbol extracted in Step S50 (if there is any datum symbol extracted) for <X>, substitutes the datum symbol extracted in Step S51 for <Y>, and substitutes the tolerance range extracted in Step S51 for <P1>.

(S57) The translation processing unit 20c changes the geometric tolerance information about the same operator group as the operator symbol extracted in Step S12 to the explanatory text created in Step S56 (the original geometric tolerance information may be left separately).

(S58) The translation processing unit 20c extracts, from the geometric tolerance DB 20e, the shape ID registered in the same Index as the operator whose operator symbol is the positional tolerance.

(S59) The translation processing unit 20c extracts the shape ID corresponding to the datum symbol extracted in Step S51 from the geometric tolerance DB 20e.

(S60) The translation processing unit 20c creates an angular dimension and a positional dimension between the two shapes from the shape IDs extracted in Steps S58 and 559. For example, it is assumed that the shape ID extracted in Step S58 is “cylinder 001” and the shape ID extracted in Step S59 is “face 001”. In that case, the translation processing unit 20c uses the datum direction stored in advance, for example, to create an angular dimension representing the angle between the central axis direction of the opening 31d and the normal direction of the faces 31a, 31b, 31c. The translation processing unit 20c creates a positional dimension that represents the distance between the central axis of the opening 31d and the faces 15b and 15c, for example, based on the additional information.

(S61) The translation processing unit 20c generates dimensional information in which the dimensional tolerance (allowable angle or allowable range of the positional dimension) calculated in Steps S54 and S55 is added to the angular dimension and the positional dimension created in Step S60, and then terminates the conversion processing for the positional tolerance.

The shape ID extracted in Step S52 is held in the RAM 22, for example, in association with the explanatory text created in Step S57 and the dimensional information obtained in Step S61. Then, in the processing of Step S16 described above, the explanatory text and dimensional information are displayed in association with the shape indicated by the ID.

The order of the processes described above is not limited to the order illustrated in FIGS. 8, 10, 11, and 12, but may be accordingly changed.

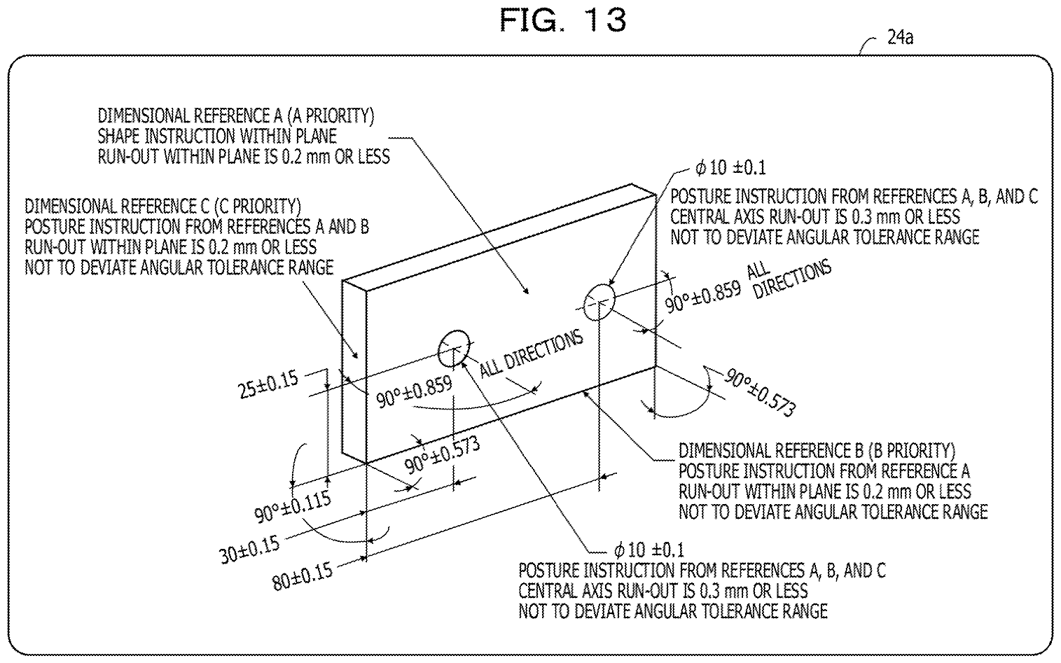

FIG. 13 illustrates a display example of conversion result information displayed on a display.

FIG. 13 illustrates a result of converting the geometric tolerance information of the drawing data 30 for the article 31 whose shape or structure is defined by the geometric tolerance method as illustrated in FIG. 7 into conversion result information including a word described using the dimensional tolerance method based on the conversion table.

By referring to such conversion result information, even users who are unfamiliar with the geometric tolerance method may easily understand the drawing data 30 created using the geometric tolerance method, thus enabling suppression of variations in user interpretation.

Although the above description is given of the conversion processing when the types of geometric tolerance included in the extracted geometric tolerance information are flatness, squareness, and positional tolerance, the present disclosure is not limited thereto. For other types of geometric tolerances, the conversion processing may be applied in the same manner by preparing a conversion table including words to be described using the dimensional tolerance method.

The output unit 20d may display a part of the information instead of displaying all the conversion result information as illustrated in FIG. 13 on the display 24a.

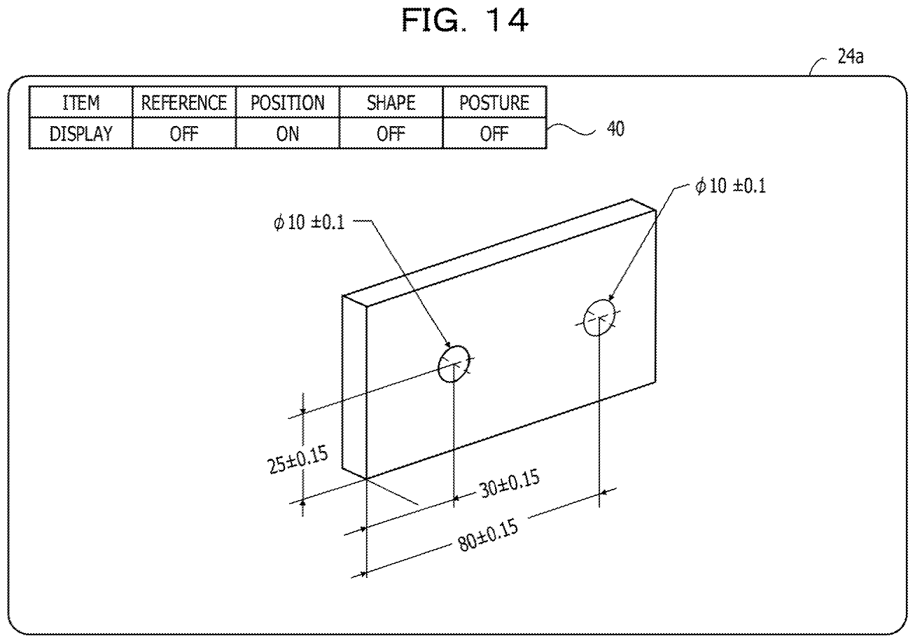

FIG. 14 is a diagram illustrating an example of displaying a group of selection buttons for selecting information to be displayed on the display.

The example of FIG. 14 illustrates a selection button group 40 for selectively displaying four types of information, including reference, position, shape, and posture, among the conversion result information. For example, when the input unit 20a detects the user clicking a selection button for specific information in the selection button group 40 with a mouse or the like, the output unit 20d switches whether to output the specific information to the display 24a. In the example of FIG. 14, the display of information related to the position is turned on and the display of other information is turned off among the conversion result information.

By adopting such a function, the user may easily confirm desired information in the conversion result information.

When such a function is used, the conversion result information is classified into respective types (four types in the above example) in advance by the translation processing unit 20c or the output unit 20d.

Alternatively, the output unit 20d may highlight the information selected by the user instead of switching whether to output the specific information to the display 24a.

The output unit 20d may display information about a measurement method on the display 24a together with the conversion result information as described below.

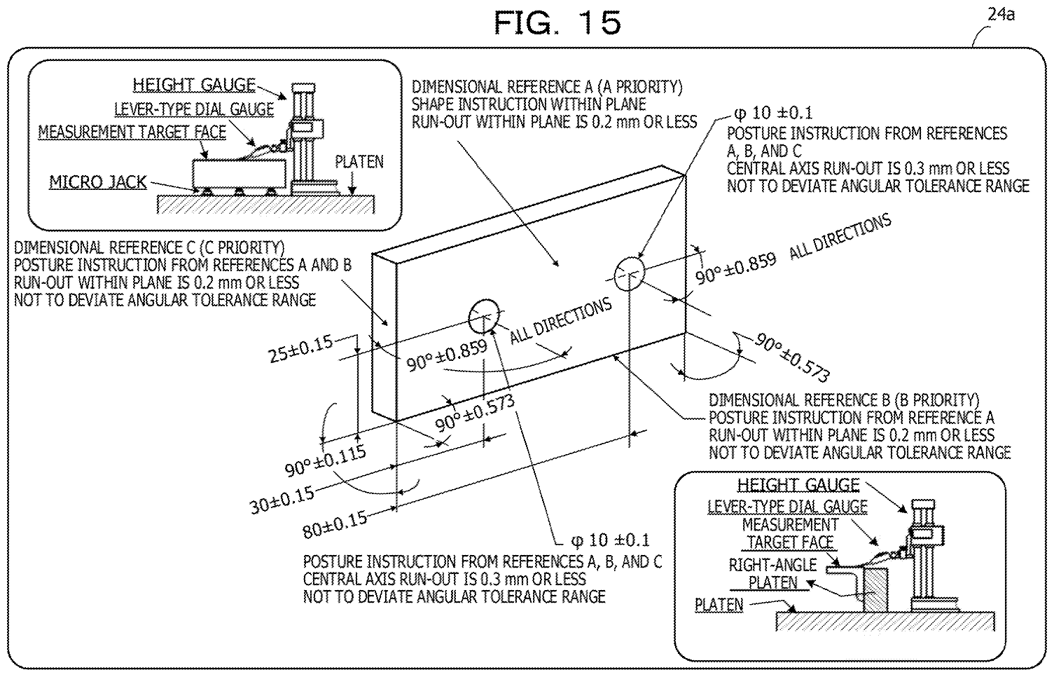

FIG. 15 illustrates an example of displaying information on a measurement method together with the conversion result information.

In the example of FIG. 15, the image represents how the measurement is performed by the measuring instrument together with the image of the measuring instrument.

Thus, in the inspection process, the measurer may easily grasp the measurement method.

The output unit 20d may display the geometric tolerance information held corresponding to the conversion result information on the display 24a together with the conversion result information or by switching to the conversion result information.

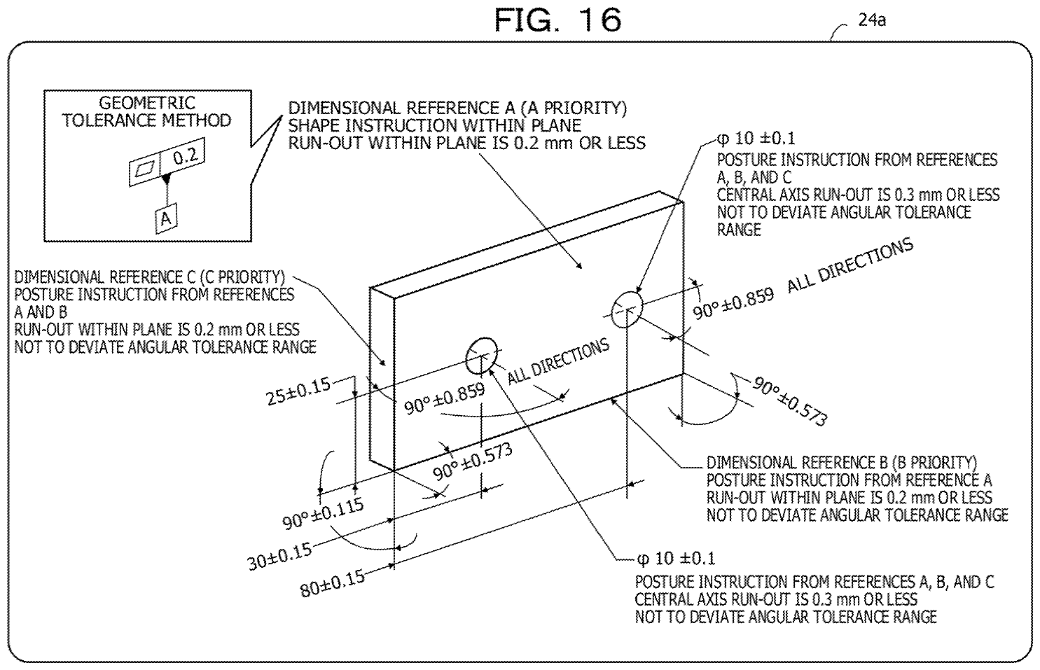

FIG. 16 illustrates an example of simultaneously displaying some geometric tolerance information and the conversion result information on the display.

In the example of FIG. 16, the geometric tolerance information about the flatness and the conversion result information are simultaneously displayed on the display 24a.

By adopting such a function, it is possible to encourage a user who is unfamiliar with the geometric tolerance method to learn the geometric tolerance method.

The output unit 20d may alternately switch the stored geometric tolerance information and the conversion result information obtained by converting the geometric tolerance information on the display 24a based on an instruction from the user.

(Method for converting Dimensional Tolerance Information Into Geometric Tolerance Information)

The processing of converting dimensional tolerance information into geometric tolerance information may also be implemented using the information processing apparatus 20 illustrated in FIG. 2.

The procedures will be described below.

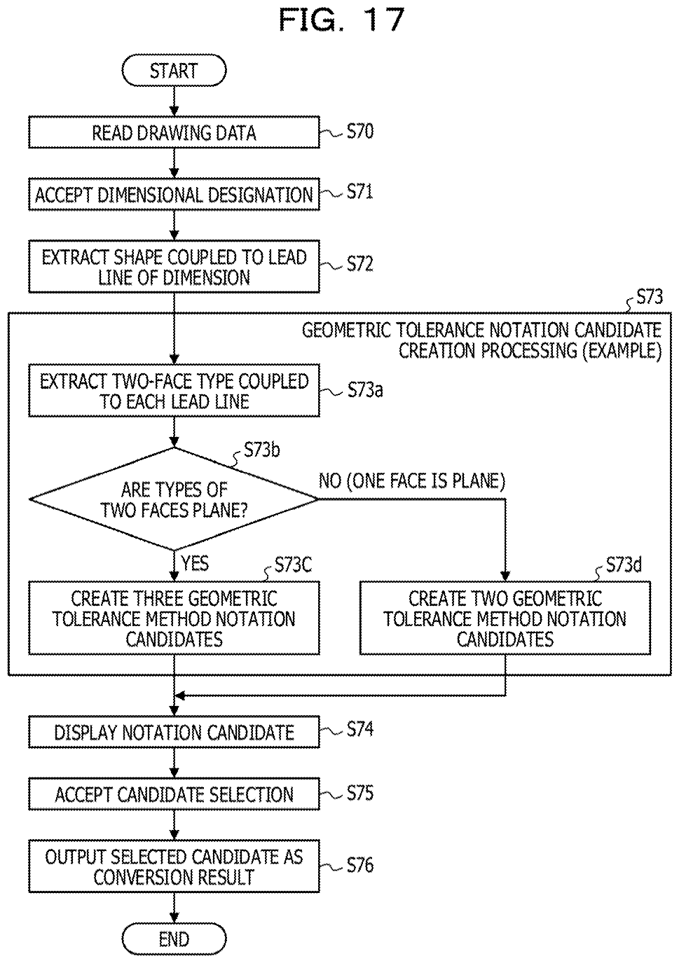

FIG. 17 illustrates an exemplary flow of processing for converting dimensional tolerance information into geometric tolerance information.

(S70) The information processing apparatus 20 reads from the outside drawing data in which the shape or structure of the article are defined by a dimensional tolerance method, for example.

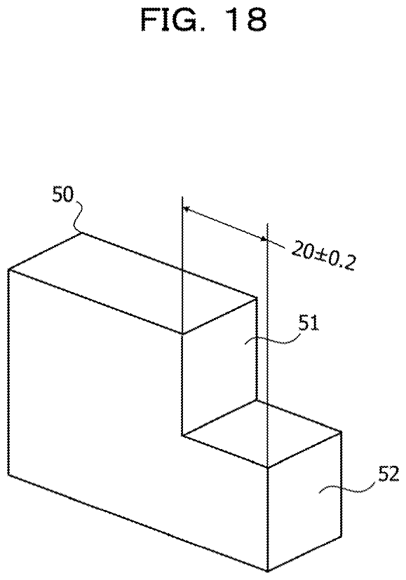

FIG. 18 illustrates an example in which a part of a certain article is defined by the dimensional tolerance method.

In FIG. 18, it is defined that the distance between the faces 51 and 52 of the article 50 is 2θ±0.2 mm. Dimensional tolerance information related to such dimensions is included in the additional information of the drawing data.

(S71) The information processing apparatus 20 displays a 2D image or a 3D image (including dimensional values and lead lines of dimensions) of an article based on the drawing data on the display 24a, and receives dimensional designation using the input device 25a such as a mouse by the user.

(S72) The information processing apparatus 20 extracts the shape coupled to the lead line having the designated dimension from the drawing data.

(S73) The information processing apparatus 20 performs processing of creating a geometric tolerance notation candidate based on the extracted shape.

Hereinafter, description is given of a processing example when the extracted shape is two faces.

(S73a) The information processing apparatus 20 extracts from the drawing data the two types (planar or non-planar) coupled to each lead line of dimensions.

(S73b) The information processing apparatus 20 determines whether or not the type of the two faces is a plane. When the type of the two faces is a plane, the processing of Step S73c is performed, and when one face is a plane and the other face is not a plane, the processing of Step S73d is performed.

(S73c) The information processing apparatus 20 creates the following three as candidates for the notation of the geometric tolerance method. The first candidate is a notation in which the first face of the two planar faces is a datum with a datum symbol “A” and geometric tolerance information about the positional tolerance is associated with the second face. The second candidate is a notation in which the second face of the two planar faces is a datum with a datum symbol “A” and geometric tolerance information about the positional tolerance is associated with the first face. The third candidate is a notation in which no datum is set and geometric tolerance information about the positional tolerance is associated with the two faces.

(573d) The information processing apparatus 20 creates the following two as candidates for the notation of the geometric tolerance method. The first candidate is a notation in which a face determined as a plane is a datum with a datum symbol “A” and geometric tolerance information about the positional tolerance is associated with the other face. The second candidate is a notation in which no datum is set and geometric tolerance information about the positional tolerance is associated with the two faces.

(S74) The information processing apparatus 20 displays the notation candidates created in Step S73 on the display 24a.

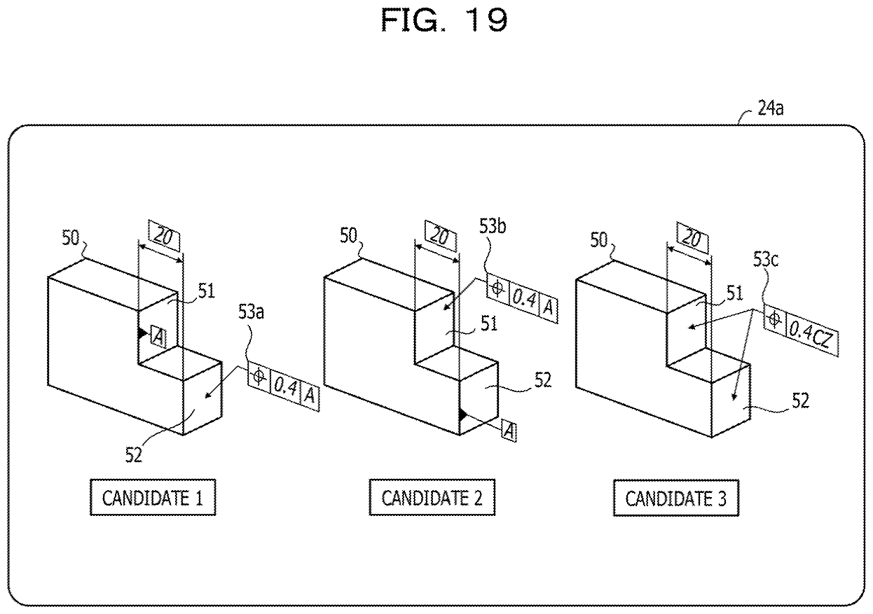

FIG. 19 illustrates a display example of candidates for notation using the geometric tolerance method.

The example of FIG. 19 illustrates three geometric tolerance method notation candidates for the dimensional tolerance method notation illustrated in FIG. 18.

The first candidate is a notation in which the face 51 of the two planar faces is a datum of the datum symbol “A” and the face 52 is associated with geometric tolerance information about the positional tolerance. The geometric tolerance information is represented in a tolerance entry frame 53a. The tolerance entry frame 53a represents, from the left, a symbol representing the positional tolerance, a tolerance range “0.4”, and the datum symbol “A” as the geometric tolerance information.

The second candidate is a notation in which the face 52 of the two planar faces is a datum with a datum symbol “A” and the face 51 is associated with geometric tolerance information about the positional tolerance. The notation of the tolerance entry frame 53b is the same as that of the first candidate tolerance entry frame 53a.

The third candidate is a notation in which no datum is set and geometric tolerance information about the positional tolerance is associated with the faces 51 and 52. The tolerance entry frame 53c represents, from the left, a symbol representing the positional tolerance and a tolerance range “0.4 CZ” as geometric tolerance information. “CZ” means a common zone, and is a symbol used when one tolerance range is applied to a plurality of distant shapes.

The information processing apparatus 20 receives selection of a candidate using the input device 25a such as a mouse by the user.

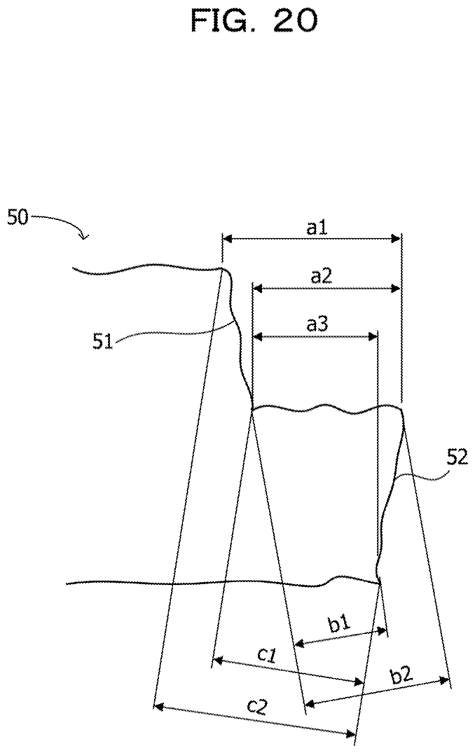

FIG. 20 is a diagram illustrating an example of a case where each candidate is applied.

Each face of the article 50 may include shaking as illustrated in FIG. 20 after manufacturing, and the vertical portion in the drawing data may be slightly inclined after manufacturing.

For example, when focusing on the length in the horizontal direction such as the dimensions a1, a2, and a3, the “candidate 3” illustrated in FIG. 19 is selected, and when focusing on the length from the face 51 as in the dimensions b1 and b2, “candidate 1” illustrated in FIG. 19 is selected. When focusing on the length from the face 52 as in the dimensions c1 and c2, “candidate 2” illustrated in FIG. 19 is selected.

(S76) The information processing apparatus 20 outputs the candidate selected by the user as a conversion result. For example, the information processing apparatus 20 outputs the geometric tolerance information about the selected candidate (deletes the geometric tolerance information about the non-selected candidate) to the outside. The outputted geometric tolerance information is used, for example, as input data for the measuring instrument The information processing apparatus 20 may store the geometric tolerance information about the selected candidate in the HDD 23.

As described above, the above processing contents may be realized by causing the information processing apparatus 20 to execute a program.

The program may be recorded on a computer-readable recording medium (for example, the recording medium 26a). As the recording medium, for example, a magnetic disk, an optical disk, a magneto-optical disk (MO), and a semiconductor memory may be used. The magnetic disk includes an FD and an HDD. The optical disk includes a CD, a CD-recordable (R)/rewritable (RW), a DVD, and a DVD-RJRW. The program may be recorded and distributed on a portable recording medium. In that case, the program may be copied from a portable recording medium to another recording medium (for example, HDD 23) and executed.

Although an aspect of the geometric tolerance and dimensional tolerance conversion program and the information processing apparatus of the present disclosure have been described above based on the embodiments, the geometric tolerance and dimensional tolerance conversion program and the information processing apparatus are merely examples and the present disclosure is not limited to the description above.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A non-transitory computer-readable storage medium for storing a geometric tolerance and dimensional tolerance conversion program which causes a processor to perform processing for object recognition, the processing comprising:
extracting geometric tolerance information from drawing data in which the shape or structure of an article is defined by a geometric tolerance method, the geometric tolerance information including one or more of parameters thus set for the article, the one or more of parameters including at least any of a geometric tolerance type, a tolerance range, and a datum symbol;
generating a word corresponding to the geometric tolerance information based on correspondence information by referring to a storage unit that stores the correspondence information including words to explain, using a dimensional tolerance method, each of a plurality of types of geometric tolerances; and
outputting conversion result information including the generated word.

2. The non-transitory computer-readable storage medium according to claim 1, wherein
the correspondence information includes a word indicating that a shape corresponding to the datum symbol is a dimensional reference in a dimensional tolerance method, and a word indicating a priority order of the dimensional reference.

3. The non-transitory computer-readable storage mediumaccording to claim 1, wherein
the correspondence information includes information indicating a calculation procedure for calculating a dimensional tolerance defined by a dimensional tolerance method using a tolerance range defined by a geometric tolerance method,
the program causing the computer to execute processing of
calculating the dimensional tolerance corresponding to the extracted geometric tolerance information based on the calculation procedure, and
outputting the conversion result information including dimensional information in which the calculated dimensional tolerance is added to the dimensional value of the article.

4. The non-transitory computer-readable storage medium according to claim 1, wherein
the correspondence information includes a word describing a tolerance range that is not expressed by a dimensional tolerance method.

5. The non-transitory computer-readable storage medium according to claim 1, the processing further comprising:
displaying the geometric tolerance information corresponding to the conversion result information on a display device together with the conversion result information or by replacing with the conversion result information.

6. The non-transitory computer-readable storage medium according to claim 1, wherein the conversion result information is input data of a measuring instrument that measures the dimensions of the article after manufacture.

7. An information processing apparatus comprising:
a memory configured to store correspondence information, the correspondence information including a word explaining each of a plurality of types of geometric tolerances using a dimensional tolerance method; and
a processor coupled to the memory, the processor being configured to
extract geometric tolerance information from drawing data in which the shape or structure of an article is defined by a geometric tolerance method, the geometric tolerance information including one or more of parameters thus set for the article, the one or more of parameters including at least any of a geometric tolerance type, a tolerance range, and a datum symbol,
generate a word corresponding to the geometric tolerance information based on the correspondence information by referring to the memory, and
output conversion result information including the generated word.
